(19) United States
(12) Patent Application Publication
(10) Pub. No.: US 2016/0069953 A1
(43) Pub. Date: Mar. 10, 2016

(54) TEST CIRCUIT DESIGN APPARATUS, TEST CIRCUIT DESIGN PROGRAM, AND TEST CIRCUIT

(71) Applicant: Mitsubishi Electric Corporation, Chiyoda-ku (JP)

(72) Inventors: Nobuhide TAKASHINA, Chiyoda-ku (JP); Hiroshi AOKI, Chiyoda-ku (JP)

(73) Assignee: Mitsubishi Electric Corporation, Chiyoda-ku (JP)

(21) Appl. No.: 14/614,490

(22) Filed: Feb. 5, 2015

(30) Foreign Application Priority Data
Sep. 4, 2014 (JP) 2014-179823

(51) Int. Cl. G01R 31/317

(52) U.S. Cl. CPC G01R 31/3172; G01R 31/31712

(57) ABSTRACT

Test information data includes a signal identifier and time period information which are being associated with a terminal identifier. An overlapping number counting part counts a first type overlapping number for each unit time period, based on the test information data. The first type overlapping number indicates the number of terminal identifiers being associated with time period information indicating an input time period which includes a unit time period and being associated with a first type signal identifier identifying a first type input signal. A determination circuit number decision part decides that the maximum overlapping number among the first type overlapping number of each unit time period is to be a first type determination circuit number. A design data generation part generates design data for a test circuit having the same number of first type determination circuits as the first type determination circuit number.

### CROSS-REFERENCE TO RELATED APPLICATIONS

This application is based on and claims the benefit of priority from Japanese Patent Application No. 2014-179823, filed in Japan on Sep. 4, 2014, the content of which is incorporated herein by reference in its entirety.

### TECHNICAL FIELD

The present invention relates to a technique for testing an input signal of a circuit.

### BACKGROUND ART

When an LSI (Large Scale Integration) is implemented on a substrate, a logic design error in the substrate or a design error in a peripheral device may lead to a case where the correct input signal is not inputted to an input terminal of the LSI, causing the LSI to malfunction.

For this reason, after the LSI is implemented on the substrate, a functional test of the LSI is conducted at normal operating speed. Then, if the LSI malfunctions, it is necessary to identify the cause of a malfunction by debugging.

However, it requires effort to identify the cause of a malfunction by the functional test and debugging.

For example, to identify the cause of a malfunction using a logic analyzer, it takes time to prepare, set, and analyze various signals to be monitored. There are also restrictions on the signals that can be monitored. Further, even if a faulty operation of a functional block of the LSI is detected, in order to judge whether the faulty operation is caused by a fault in the functional block or an invalid signal being inputted to the LSI, it is necessary to trace back the signals from the functional block. As described above, it is not easy to identify the cause of a malfunction.

As a technique for testing input/output terminals of an LSI after the LSI is implemented on a substrate, there is a technique called boundary scan. With the boundary scan technique, a continuity test between the input/output terminals of the LSI and the substrate can be conducted.

However, in order to conduct a boundary scan test, it is necessary to sample an input signal inputted to an input terminal of the LSI using boundary scan cells, output a result of sampling bit by bit, and sequentially test the outputted results. For this reason, it is difficult to test with boundary scan all monitoring results in a period of a single operating cycle of the LSI.

It is therefore difficult to test with boundary scan whether input operations on the LSI are valid in a plurality of successive cycles.

### CITATION LIST

### Patent Literature

[Patent Literature 1] JP 04-297880 A
[Patent Literature 2] JP 08-116033 A
[Patent Literature 3] JP 05-087889 A

### SUMMARY OF INVENTION

### Technical Problem

It is an object of the present invention to test an input signal of a test target circuit.

### Solution to Problem

A test circuit design apparatus according to the present invention includes
a test information data storage part that stores test information data, including a signal identifier and time period information which are being associated with a terminal identifier identifying an input terminal, for each input terminal of a test target circuit having a plurality of input terminals, the signal identifier identifying a type of an input signal to be inputted to the input terminal, the time period information indicating an input time period during which the input signal is inputted;
an overlapping number counting part that counts a first type overlapping number of each unit time period of a test time period during which an input signal to be inputted to the test target circuit is tested, the first type overlapping number indicating a number of terminal identifiers being associated with time period information indicating an input time period which includes the each unit time period and being associated with a first type signal identifier identifying a first type input signal, among terminal identifiers included in the test information data; and
a determination circuit number decision part that decides a first type determination circuit number indicating a number of first type determination circuits which determine whether the first type input signal is inputted, based on the first type overlapping number of each unit time period counted by the overlapping number counting part.

### Advantageous Effects of Invention

According to the present invention, a test circuit having a required number of determination circuits can be designed. Then, an input signal of a test target circuit can be tested with the test circuit.

### BRIEF DESCRIPTION OF DRAWINGS

The present invention will become fully understood from the detailed description given hereinafter in conjunction with the accompanying drawings, in which:

FIG. 1 is a functional configuration diagram of a test circuit design apparatus 100 according to a first embodiment;

FIG. 2 is a diagram illustrating an example of test information data 181 according to the first embodiment;

FIG. 3 is a diagram illustrating an example of a determination circuit database 182 according to the first embodiment;

FIG. 4 is a flowchart illustrating a test circuit design process of the test circuit design apparatus 100 according to the first embodiment;

FIG. 5 is a flowchart illustrating a determination circuit number decision process (S110) of a test circuit design part 110 according to the first embodiment;

FIG. 6 is a diagram illustrating an example of the configuration of an LSI 200 and the configuration of a test circuit 210 according to the first embodiment;

FIG. 7 is a diagram illustrating an example of a test sequence 192 according to the first embodiment;

FIG. 8 is a flowchart illustrating a test sequence generation process (S220) of a test sequence generation part 122 according to the first embodiment;

FIG. 9 is a flowchart illustrating the operation of the test circuit 210 according to the first embodiment; and

FIG. 10 is a hardware configuration diagram of the test circuit design apparatus 100 according to the first embodiment.

### DESCRIPTION OF EMBODIMENTS

In describing preferred embodiments illustrated in the drawings, specific terminology is employed for the sake of clarity. However, the disclosure of the present invention is not intended to be limited to the specific terminology so selected, and it is to be understood that each specific element includes all technical equivalents that operate in a similar manner and achieve a similar result.

### First Embodiment

An embodiment according to which a test circuit for testing an input signal of a test target circuit is designed will be described.

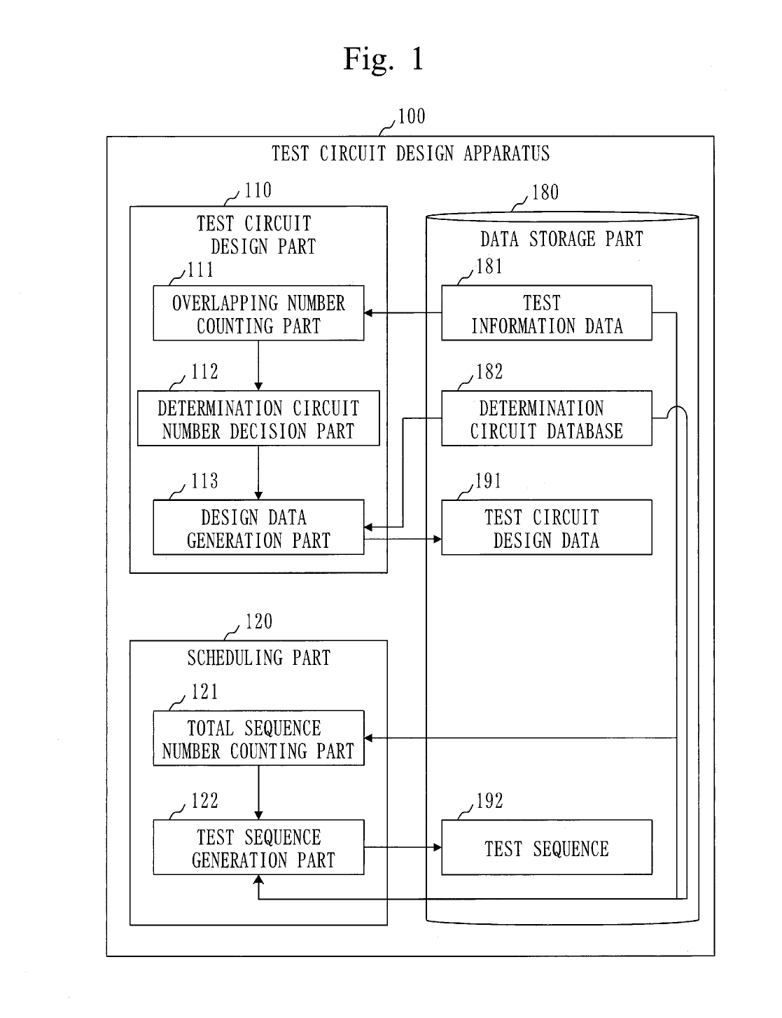

FIG. 1 is a functional configuration diagram of a test circuit design apparatus 100 according to a first embodiment.

With reference to FIG. 1, the functional configuration of the test circuit design apparatus 100 according to the first embodiment will be described. Note that the functional configuration of the test circuit design apparatus 100 may be different from the functional configuration illustrated in FIG. 1.

The test circuit design apparatus 100 is an apparatus that designs a test circuit for testing an input signal to be inputted to an input terminal of an LSI. The term LSI stands for Large Scale Integration and signifies an integrated circuit. In the first embodiment, the LSI is a test target circuit to be tested.

The test circuit design apparatus 100 has a test circuit design part 110, a scheduling part 120, and a data storage part 180.

The data storage part 180 (an example of a test information data storage part and a determination circuit database storage part) stores data used in the test circuit design apparatus 100. For example, the data storage part 180 stores test information data 181, a determination circuit database 182, test circuit design data 191, and a test sequence 192.

The test information data 181 is data indicating the type of an input signal to be inputted to each input terminal of the LSI during each input time period. For example, the test information data 181 includes a first signal identifier and first time period information which are being associated with a first terminal identifier identifying a first input terminal. The first signal identifier identifies a first type input signal to be inputted to the first input terminal, and the first time period information indicates a first input time period during which the first type input signal is inputted to the first input terminal.

The determination circuit database 182 is a database including determination circuit data representing a determination circuit for determining the type of an input signal, for each type of input signal. For example, the determination circuit database 182 includes a first type determination circuit identifier and first type determination circuit data which are being associated with the first signal identifier. The first type determination circuit identifier identifies a first type determination circuit for determining whether the first type input signal has been inputted, and the first type determination circuit data represents the first type determination circuit.

The test circuit design data 191 is design data for a test circuit having a required number of determination circuits for each type of input signal. For example, the test circuit design data 191 includes determination circuit data for the first type determination circuit.

The test sequence 192 is data indicating a test schedule for each determination circuit included in the test circuit. For example, the test sequence 192 includes the first terminal identifier and the first time period information which are being associated with a first determination circuit identifier identifying a first determination circuit among first type determination circuits. The first terminal identifier identifies the first input terminal to which the first type input signal is inputted, and the first input time period information indicates the first input time period during which the first type input signal is inputted to the first input terminal.

The test circuit design part 110 generates the test circuit design data 191, based on the test information data 181 and the determination circuit database 182.

The test circuit design part 110 has an overlapping number counting part 111, a determination circuit number decision part 112, and a design data generation part 113.

The overlapping number counting part 111 counts the number of input terminals to which an input signal of the same type is inputted during the same time period, for each type of input signal, based on the test information data 181. This number will hereinafter be referred to as an overlapping number. For example, the overlapping number counting part 111 counts a first type overlapping number indicating the number of input terminals to which the first type input signal is inputted, for each unit time period.

The determination circuit number decision part 112 decides a required number of determination circuits for each type of input signal, based on the overlapping number of each time period. For example, the determination circuit number decision part 112 decides that the maximum overlapping number among the first type overlapping number of each time period is to be the number of first type determination circuits.

The design data generation part 113 generates the test circuit design data 191, based on the required number of determination circuits for each type of input signal. For example, the design data generation part 113 generates the test circuit design data 191, using first type determination circuit data included in the determination circuit database 182. The test circuit design data 191 is design data for a test circuit, and the test circuit is a circuit having a required number of first type determination circuits.

The scheduling part 120 generates the test sequence 192, based on the test information data 181 and the determination circuit database 182.

The scheduling part 120 has a total sequence number counting part 121 and a test sequence generation part 122.

The total sequence number counting part 121 counts the number of input time periods during which an input signal is inputted to at least any one of the input terminals. This number of input time periods will hereinafter be referred to as a total sequence number.

The test sequence generation part 122 generates the test sequence 192, based on the total sequence number, the test information data 181, and the determination circuit database 182. For example, the test sequence generation part 122 obtains from the test information data 181 the first type signal identifier and the first time period information which are being associated with the first terminal identifier, and obtains from the determination circuit database 182 the first type determination circuit identifier which is being associated with the first type signal identifier. Then, the test sequence generation part 122 generates the test sequence 192 by associating the first terminal identifier and the first time period information with the first determination circuit identifier which is based on the first type determination circuit identifier. The test sequence generation part 122 also includes in the test sequence 192 a sequence number for each input time period counted in the total sequence number.

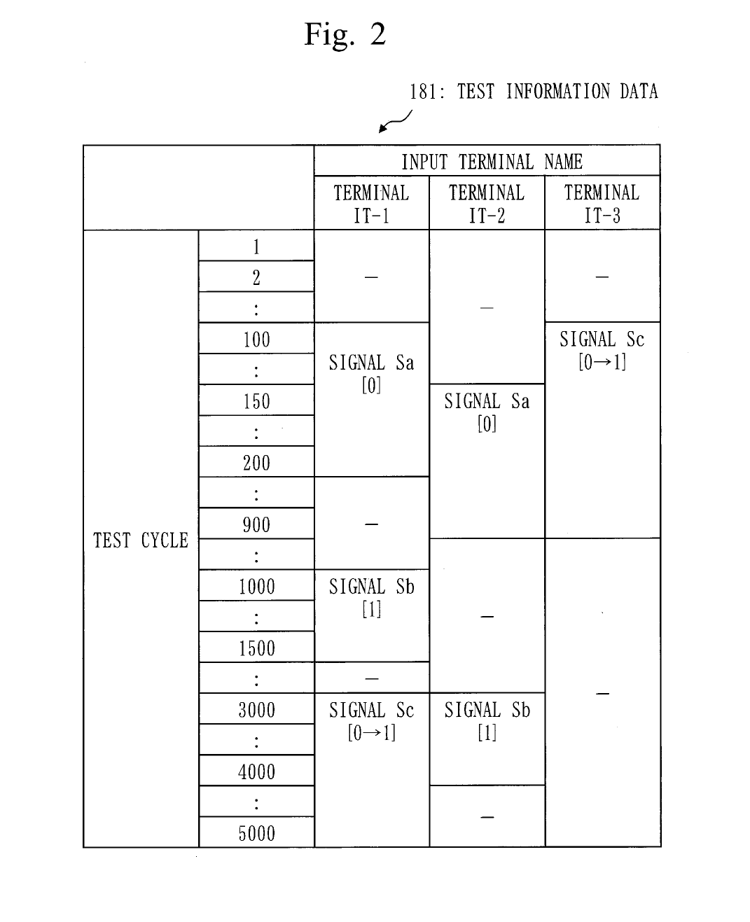

FIG. 2 is a diagram illustrating an example of the test information data 181 according to the first embodiment.

With reference to FIG. 2, an example of the test information data 181 according to the first embodiment will be described.

The test information data 181 indicates an input signal name which is being associated with an input terminal name and test cycles.

The input terminal name is an example of a terminal identifier identifying an input terminal. The input signal name is an example of a signal identifier identifying an input signal.

The test cycles indicate elapsed time since the start of a test. A unit time of the elapsed time is 1 cycle, and 1 cycle corresponds to 1 clock of the LSI. The entire period from the first test cycle to the last test cycle signifies a test time period during which the test is conducted.

The test information data 181 may be data in a table format, data written in a verification language (assertion language, for example), or data in other formats.

For example, the test information data 181 indicates that a signal Sa is inputted to a terminal IT-1 during an input time period from cycle 100 through cycle 200. The test information data 181 also indicates that a signal Sb is inputted to the terminal IT-1 during an input time period from cycle 1000 through cycle 1500, and that a signal Sc is inputted to the terminal IT during an input time period from cycle 3000 through cycle 5000.

The signal Sa is an input signal having a value 0. The signal Sb is an input signal having a value 1. The signal Sc is an input signal whose value changes from 0 to 1 during an input time period.

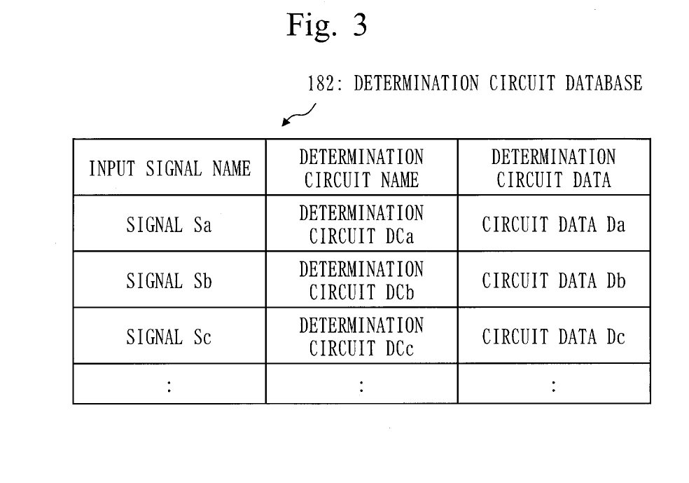

FIG. 3 is a diagram illustrating an example of the determination circuit database 182 according to the first embodiment.

With reference to FIG. 3, an example of the determination circuit database 182 according to the first embodiment will be described.

The determination circuit database 182 includes a determination circuit name and determination circuit data which are being associated with an input signal name. The determination circuit name is an example of a determination circuit identifier identifying a determination circuit.

The determination circuit data is data representing a determination circuit. For example, the determination circuit dada is data in which the configuration of a determination circuit is written in an HDL. The term HDL stands for Hardware Description Language.

For example, the determination circuit database 182 includes a determination circuit DCa and circuit data Da which are being associated with the signal Sa.

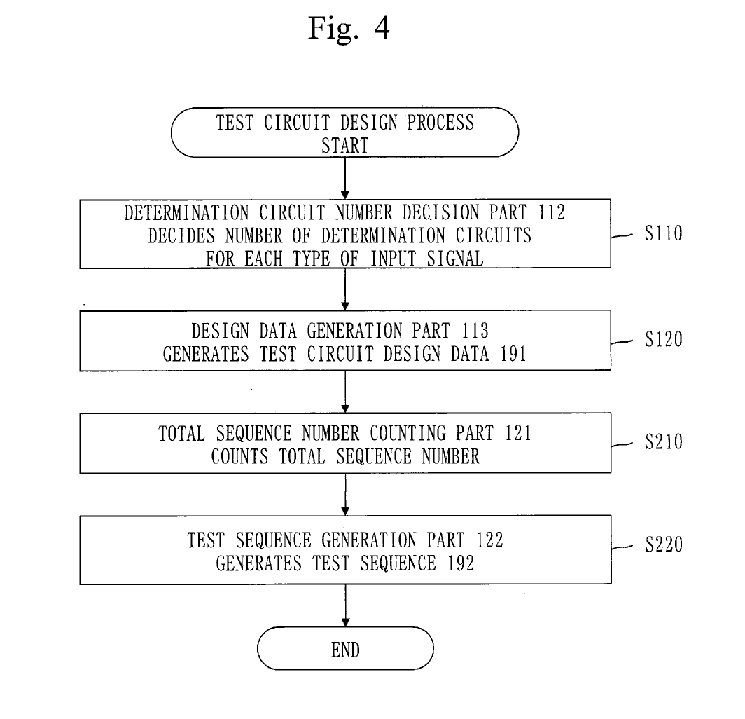

FIG. 4 is a flowchart illustrating a test circuit design process of the test circuit design apparatus 100 according to the first embodiment.

With reference to FIG. 4, the test circuit design process of the test circuit design apparatus 100 according to the first embodiment will be described. Note that the test circuit design process of the test circuit design apparatus 100 may be different from the test circuit design process illustrated in FIG. 4.

In S110, the overlapping number counting part 111 counts the overlapping number of each test cycle for each type of input signal, based on the test information data 181.

Then, the determination circuit number decision part 112 decides the number of determination circuits for each type of input signal, based on the overlapping number of each test cycle.

After S110, processing proceeds to S120.

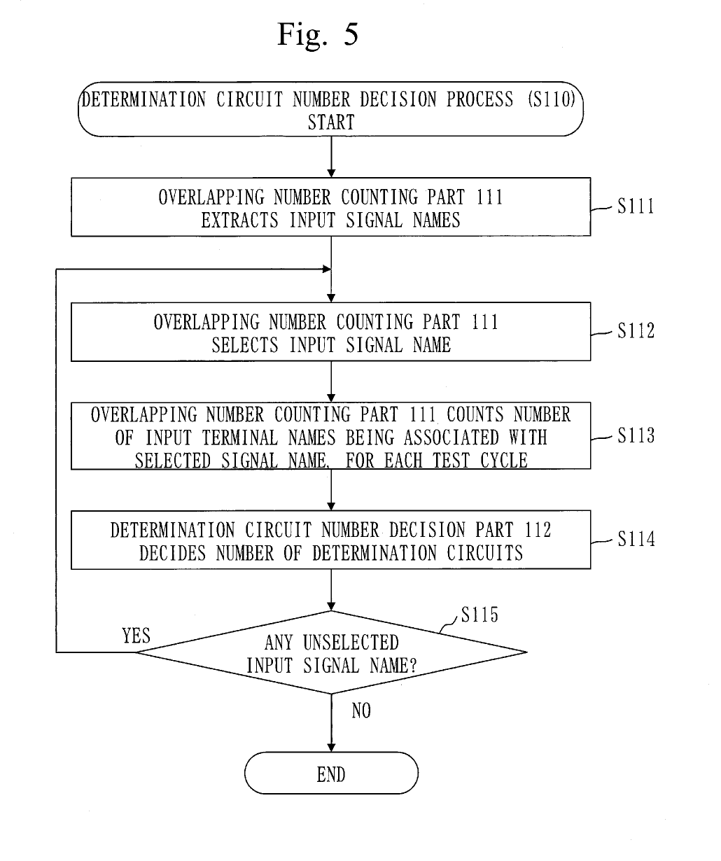

FIG. 5 is a flowchart illustrating a determination circuit number decision process (S110) of the test circuit design part 110 according to the first embodiment.

With reference to FIG. 5, the determination circuit number decision process (S110) of the test circuit design part 110 according to the first embodiment will be described. Note that the determination circuit number decision process (S110) of the test circuit design part 110 may be different from the determination circuit number decision process (S110) illustrated in FIG. 5.

In S111, the overlapping number counting part 111 extracts input signal names from the test information data 181.

For example, the overlapping number counting part 111 extracts three signal names (signal Sa, signal Sb, and signal Sc) from the test information data 181 of FIG. 2.

After S111, processing proceeds to S112.

In S112, the overlapping number counting part 111 selects an unselected input signal name from the input signal names extracted in S111. The input signal name which has been selected will hereinafter be referred to as a selected signal name.

For example, the overlapping number counting part 111 selects the signal Sa from the three input signal names (signal Sa, signal Sb, and signal Sc).

After S112, processing proceeds to S113.

In S113, the overlapping number counting part 111 counts the number of input terminal names being associated with the selected signal name, for each test cycle.

In the case of the test information data 181 of FIG. 2, the number of input terminal names being associated with the signal Sa is one (terminal IT-1) from cycle 100 through cycle 149, and two (terminal IT-1 and terminal IT-2) from cycle 150 through cycle 900. In other test cycles, the number of input terminal names associated with the signal Sa is zero.

After S113, processing proceeds to S114.

In S114, the determination circuit number decision part 112 decides that the maximum number among the number of input terminal names of each test cycle is to be the number of determination circuits.

In the case of the test information data 181 of FIG. 2, the number of determination circuits for the signal Sa is decided to be two.

After S114, processing proceeds to S115.

In S115, the overlapping number counting part 111 determines whether there is any unselected input signal name which has not been selected in S112.

If there is any unselected input signal name (YES), processing returns to S112.

If there is no unselected input signal name (NO), the determination circuit number decision process (S110) ends.

After S110, processing proceeds to S120 (see FIG. 4).

In S120, the design data generation part 113 generates the test circuit design data 191, based on the determination circuit number for each type of input signal decided in S110. The test circuit design data 191 is design data for the test circuit 210. The test circuit 210 is a circuit having, for each type of input signal, the same number of determination circuits as the determination circuit number. For example, the test circuit design data 191 is written in the HDL.

At this time, the design data generation part 113 obtains from the determination circuit database 182 the determination circuit data being associated with the input signal name for each type of input signal. Then, the design data generation part 113 generates the test circuit design data 191, using the determination circuit data for each type of input signal.

For example, a designer stores basic design data to be a basis for the test circuit design data 191 in the data storage part 180 in advance. Then, the design data generation part 113 generates the test circuit design data 191 by editing the basic design data, such as by inserting the determination circuit data for each determination circuit.

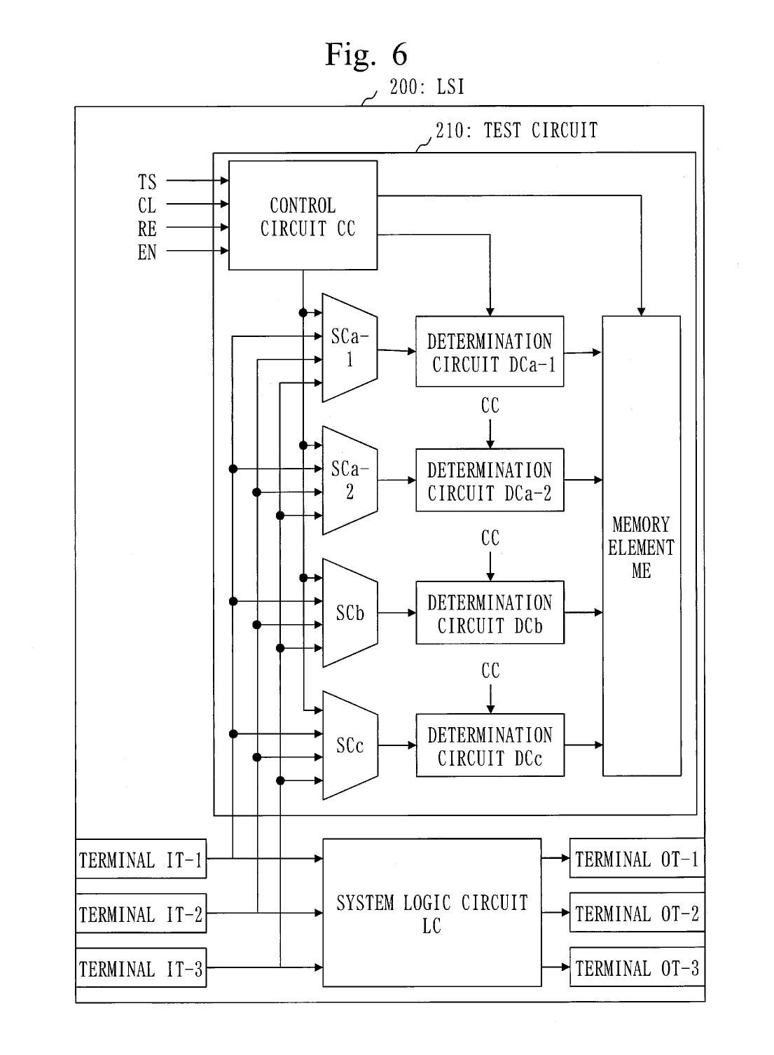

When the number of determination circuits for the signal Sa is two, the number of determination circuits for the signal Sb is one, and the number of determination circuits for the signal Sc is one, the design data generation part 113 generates the test circuit design data 191 representing the test circuit 210 as illustrated in FIG. 6.

After S120, processing proceeds to S210.

FIG. 6 is a diagram illustrating an example of the configuration of an LSI 200 and the configuration of the test circuit 210 according to the first embodiment.

With reference to FIG. 6, an example of the configuration of the LSI 200 and the configuration of the test circuit 210 according to the first embodiment will be described.

In FIG. 6, lines connecting components represent signal lines, and arrows of the signal lines indicate the input directions of the signals.

The LSI 200 is a test target circuit, and has three input terminals (IT-1, IT-2, and IT-3), a system logic circuit LC, and three output terminals (OT-1, OT-2, and OT-3).

The three input terminals are terminals to which input signals are inputted from the outside of the LSI 200.

The system logic circuit LC is a circuit that processes the input signals inputted to the three input terminals and generates output signals.

The three output terminals are terminals from which the output signals generated by the system logic circuit LC are outputted to the outside of the LSI 200.

The LSI 200 further has the test circuit 210 that tests the types of input signals inputted to the three input terminals.

The test circuit 210 has two determination circuits for the signal Sa (DCa-1 and DCa-2), a determination circuit DCb for the signal Sb, and a determination circuit DCc for the signal Sc.

The test circuit 210 also has a memory element ME that stores test results of the determination circuits.

The test circuit 210 further has the following components.

The test circuit 210 has a selection circuit SCa-1 for the determination circuit DCa-1 and a selection circuit SCa-2 for the determination circuit DCa-2. The test circuit 210 also has a selection circuit SCb for the determination circuit DCb and a selection circuit SCc for the determination circuit DCc.

The selection circuit selects an input terminal from the three input terminals, and causes the determination circuit to determine the type of an input signal inputted to the selected input terminal. The selection circuit is also called a selector or a multiplexer.

The test circuit 210 has a control circuit CC that controls the selection circuits and the determination circuits, based on the test sequence 192 (TS).

During each input time period during which an input signal is inputted, the control circuit CC causes the selection circuit corresponding to the type of the input signal to select the input signal, and causes the determination circuit connected to this selection circuit to test the type of the input signal.

The test sequence 192 (TS), a clock signal CL, a reset signal RE, and an enable signal EN are inputted to the test circuit CC.

The clock signal CL is a signal which occurs at each test cycle. By counting the number of times the clock signal CL occurred since the start of the test, the number of test cycles can be counted. The control circuit CC has a counter for counting the number of test cycles.

The reset signal RE is a signal for stopping the operation of the control circuit CC and initializing the control circuit CC. While the reset signal RE is being inputted, the control circuit CC does not operate. That is, upon input of the reset signal RE, the control circuit CC which is operating stops operating, and the control circuit CC also initializes the counter value of the counter for counting the number of test cycles.

The enable signal EN is a signal for causing the control circuit CC to operate. The control circuit CC operates while the enable signal EN is being inputted and the reset signal RE is not being inputted.

The test sequence 192 (TS) is inputted to the control circuit CC from a memory element. The memory element that stores the test sequence 192 may be placed inside or outside the test circuit 210.

Each of the clock signal CL, the reset signal RE, and the enable signal EN may be a signal which is inputted from the outside of the LSI 200, a signal which is branched and inputted from a terminal in the LSI 200, or a signal which is generated inside the test circuit 210.

In S210 (see FIG. 4), the total sequence number counting part 121 identifies an input time period during which an input signal is inputted to at least any one of the input terminals, based on the test information data 181.

Then, the total sequence number counting part 121 counts the number of identified input time periods. The number of identified input time periods is the total sequence number.

The test information data 181 of FIG. 2 indicates that one or more input signals are inputted during three input time periods, namely, an input time period from cycle 100 through cycle 900, an input time period from cycle 1000 through cycle 1500, and an input time period from cycle 3000 and cycle 5000. Therefore, the total sequence number is three.

After S210, processing proceeds to S220.

In S220, the test sequence generation part 122 generates the test sequence 192, based on the test information data 181 and the total sequence number.

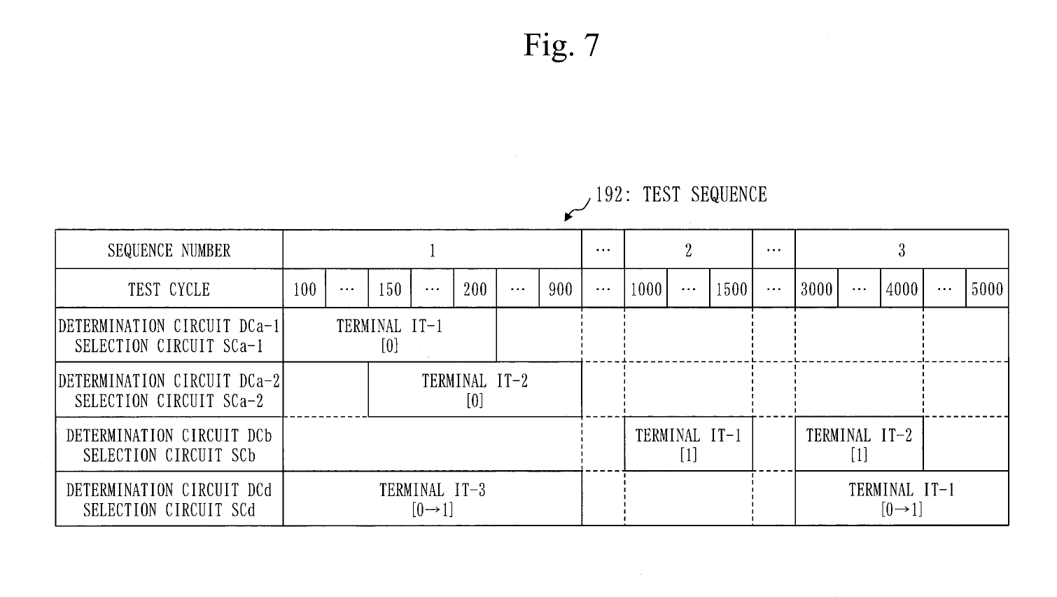

For example, the test sequence generation part 122 generates the test sequence 192 as illustrated in FIG. 7, based on the test information data 181 of FIG. 2.

After S220, the test circuit design process ends.

FIG. 7 is a diagram illustrating an example of the test sequence 192 according to the first embodiment.

With reference to FIG. 7, an example of the test sequence 192 according to the first embodiment will be described.

The test sequence 192 includes an input terminal name (or an input terminal number) which is being associated with a sequence number, test cycles, a determination circuit name (or a determination circuit number), and a selection circuit name (or a selection circuit number).

For example, the test sequence 192 includes the terminal IT-1 which is being associated with a sequence number “1”, test cycles “100 through 200”, the determination circuit DCa-1, and the selection circuit SCa-1.

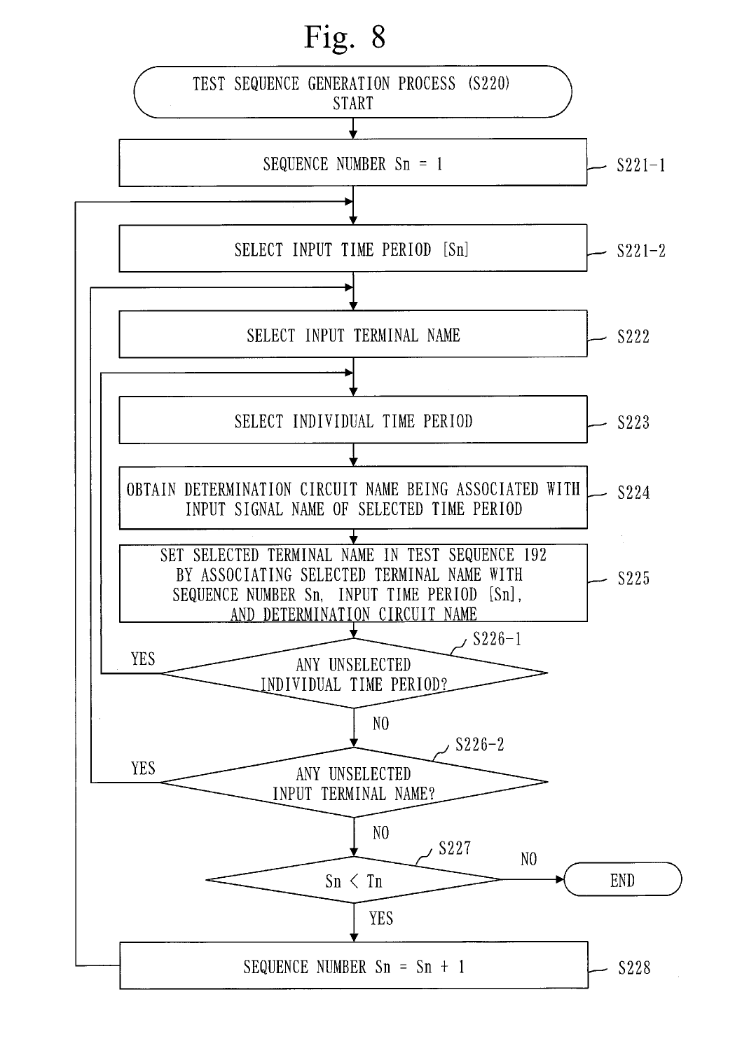

FIG. 8 is a flowchart illustrating a test sequence generation process (S220) of the test sequence generation part 122 according to the first embodiment.

With reference to FIG. 8, the test sequence generation process (S220) of the test sequence generation part 122 according to the first embodiment will be described. Note that the test sequence generation process (S220) of the test sequence generation part 122 may be different from the test sequence generation process (S220) illustrated in FIG. 8.

In S221-1, the test sequence generation part 122 sets an initial value “1” in a variable Sn for the sequence number.

After S221-1, processing proceeds to S221-2.

In S221-2, the test sequence generation part 122 selects the Sn-th input time period from the input time periods identified by the total sequence number counting part 121 (see S210). The Sn-th input time period will hereinafter be described as the input time period [Sn].

In the case of the test information data 181 of FIG. 2, the input time period [1] is the time period from cycle 100 through cycle 900.

After S221-2, processing proceeds to S222.

In S222, the test sequence generation part 122 selects an unselected input terminal name from the test information data 181. The input terminal name which has been selected will hereinafter be referred to as a selected terminal name.

For example, the test sequence generation part 122 selects the terminal IT-1 from the test information data 181 of FIG. 2.

After S222, processing proceeds to S223.

In S223, the test sequence generation part 122 selects an unselected input time period being associated with the selected terminal name, from the input time period [Sn] indicated in the test information data 181. The input time period which has been selected will hereinafter be referred to as an individual time period.

For example, the test sequence generation part 122 selects an individual time period from cycle 100 through cycle 200 being associated with the terminal IT-1, from the input time period [1] from cycle 100 through cycle 900 indicated in the test information data 181 of FIG. 2.

After S223, processing proceeds to S224.

In S224, the test sequence generation part 122 obtains from the test information data 181 the input signal name of the individual time period.

Then, the test sequence generation part 122 obtains from the determination circuit database 182 the determination circuit name being associated with the input signal name of the individual time period.

For example, the test sequence generation part 122 obtains from the test information data 181 of FIG. 2 the signal Sa which is being associated with the terminal IT-1 and the individual time period from cycle 100 through cycle 200. Then, the test sequence generation part 122 obtains from the determination circuit database 182 of FIG. 3 the determination circuit DCa which is being associated with the signal Sa.

After S224, processing proceeds to S225.

In S225, the test sequence generation part 122 sets the selected terminal name in the test sequence 192, by associating the selected terminal name with the sequence number Sn, the input time period [Sn], the determination circuit name, and the selection circuit name. The selection circuit name can be generated based on the determination circuit name. Each of the determination circuit name, the selection circuit name, and the selected terminal name can be replaced with an identification number.

For example, the test sequence generation part 122 sets the terminal IT-1 in the test sequence 192, by associating the terminal IT with the sequence number “1”, test cycles “100 through 200”, the determination circuit DCa-1, and the selection circuit SCa-1 (see FIG. 7).

When the number of determination circuits identified with the determination circuit name (see S110) is more than one, the test sequence generation part 122 assigns a different identifier to each of the determination circuits. The test sequence generation part 122 also assigns a different identifier to each of the selection circuits.

For example, the test sequence generation part 122 assigns an identifier “DCa-1” to a first determination circuit for the signal Sa, and assigns an identifier “DCa-2” to a second determination circuit for the signal Sa. The test sequence generation part 122 assigns an identifier “SCa-1” to the selection circuit for the determination circuit DCa-1, and assigns an identifier “SCa-2” to the selection circuit for the determination circuit DCa-2 (see FIG. 7).

When the number of determination circuits identified with the determination circuit name (see S110) is more than one, the test sequence generation part 122 sets the selected terminal name in the test sequence 192, by associating the selected terminal name with a determination circuit name which has not been associated with any input terminal name.

For example, when the terminal IT has been set by being associated with the input time period from cycle 100 through cycle 200 and the determination circuit DCa-1, the test sequence generation part 122 sets the terminal IT-2, by associating the terminal IT-2 with the input time period from cycle 150 through cycle 900 and the determination circuit DCa-2 (see FIG. 7).

After S225, processing proceeds to S226-1.

In S226-1, the test sequence generation part 122 determines whether there is any unselected individual time period which has not been selected in S223.

If there is any unselected individual time period (YES), processing returns to S223.

If there is no unselected individual time period (NO), processing proceeds to S226-2.

In S226-2, the test sequence generation part 122 determines whether there is any unselected input terminal name which has not been selected in S222.

If there is any unselected input terminal name (YES), processing returns to S222.

If there is no unselected input terminal name (NO), processing proceeds to S227.

In S227, the test sequence generation part 122 determines whether the sequence number Sn is smaller than a total sequence number Tn.

If the sequence number Sn is smaller than the total sequence number Tn (YES), processing proceeds to S228.

If the sequence number Sn is equal to or larger than the total sequence number Tn (NO), the test sequence generation process (S220) ends.

In S228, the test sequence generation part 122 increments the sequence number Sn by one.

After S228, processing returns to S221-2.

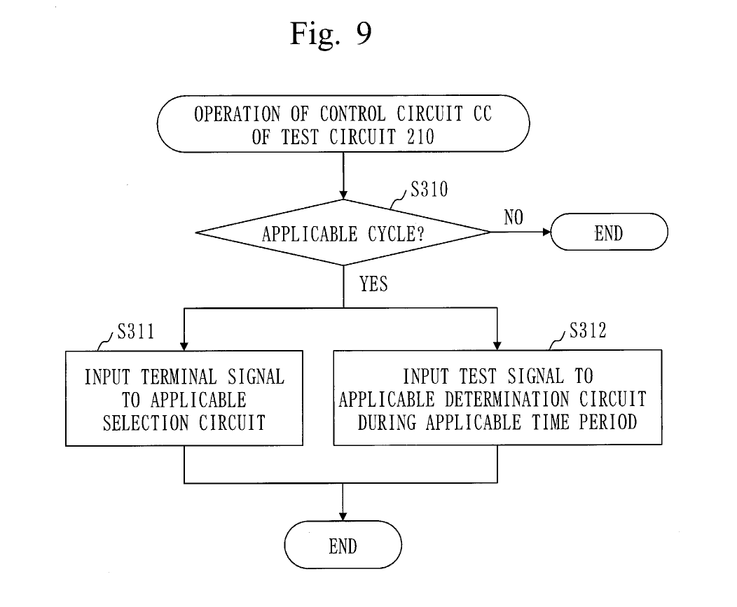

FIG. 9 is a flowchart illustrating the operation of the test circuit 210 according to the first embodiment.

With reference to FIG. 9, the operation of the control circuit CC in the test circuit 210 (see FIG. 6) according to the first embodiment will be described.

Before the start of the operation illustrated in FIG. 9, the reset signal RE is inputted to the control circuit CC of the test circuit 210, and the counter value of the counter for counting test cycles is initialized to 0. Then, the enable signal EN is inputted to the control circuit CC. Then, the control circuit CC carries out the operation illustrated in FIG. 9 upon each input of the clock signal CL.

In S310, the control circuit CC refers to the test sequence 192 (TS), and determines whether the current test cycle is an applicable cycle. The applicable cycle is a test cycle at the start of an input time period during which an input signal is inputted to at least any one of the input terminals.

At this time, the control circuit CC increments the counter value of the counter. Then, if the counter value is the same as the cycle number of the applicable cycle, the control circuit CC determines that the current test cycle is the applicable cycle.

For example, the test sequence 192 of FIG. 7 indicates that the input signal starts to be inputted to each of the terminal IT-1 and the terminal IT-3 at test cycle 100. Therefore, test cycle “100” is the applicable cycle.

If the current test cycle is the applicable cycle (YES), processing proceeds to S311 and S312.

If the current cycle is not the applicable cycle (NO), the operation at the current test cycle ends.

In S311, the control circuit CC refers to the test sequence 192 (TS), and inputs a terminal signal to an applicable selection circuit. The applicable selection circuit is a selection circuit which is identified with a selection circuit name being associated with an input time period which includes the applicable cycle (applicable time period) in the test sequence 192. The terminal signal is a signal which specifies an applicable terminal. The applicable terminal is an input terminal which is identified with an input terminal name being associated with the applicable time period and the applicable selection circuit in the test sequence 192.

Then, the applicable selection circuit selects the input terminal specified by the terminal signal among the input terminals, and continues to input to an applicable determination circuit the input signal to be inputted to the selected input terminal, until a next terminal signal is inputted. The applicable determination circuit is a determination circuit which is connected to the applicable selection circuit.

For example, the test sequence 192 of FIG. 7 indicates that the selection circuit SCa-1 and the terminal IT-1 are being associated with the input time period from cycle 100 and cycle 200. The test sequence 192 also indicates that the selection circuit SCd and the terminal IT-3 are being associated with the input time period from cycle 100 through cycle 900.

Accordingly, when test cycle 100 arrives, the control circuit CC inputs a terminal signal specifying the terminal IT-1 to the selection circuit SCa-1. Then, the selection circuit SCa-1 continues to input to the determination circuit DCa-1 (applicable determination circuit) the input signal to be inputted to the terminal IT-1, until a next terminal signal is inputted.

The control circuit CC also inputs a terminal signal specifying the terminal IT to the selection circuit SCd. Then, the selection circuit SCd continues to input to the determination circuit DCd (applicable determination circuit) the input signal to be inputted to the terminal IT-3, until a next terminal signal is inputted.

After S311, the operation at the current test cycle ends.

In S312, the control circuit CC refers to the test sequence 192 (TS), and inputs a test signal and sequence information to the applicable determination circuit during the applicable time period.

The applicable determination circuit is the determination circuit which is connected to the applicable selection circuit and which is identified with the determination circuit name being associated with the input time period which includes the applicable cycle (applicable time period) in the test sequence 192.

The test signal is a signal which specifies a determination time period for determining the type of the input signal (applicable time period).

The sequence information is information indicating the sequence number and the applicable time period.

Then, the applicable determination circuit determines the type of the input signal inputted from the applicable selection circuit while the test signal is being inputted. Then, the applicable determination circuit stores test result information including a determination result, the sequence information, and the determination circuit identifier in the memory element ME. For example, the determination result is 1-bit information.

For example, the test sequence 192 of FIG. 7 indicates that the determination circuit DCa-1 is being associated with the input time period from cycle 100 through cycle 200. The test sequence 192 also indicates that the determination circuit DCd is being associated with the input time period from cycle 100 through cycle 900.

Accordingly, the control circuit CC inputs the test signal and the sequence information to the determination circuit DCa-1 during the input time period from cycle 100 through cycle 200. Then, while the test signal is being inputted, the determination circuit DCa-1 determines whether the input signal being inputted from the selection circuit SCa-1 (applicable selection circuit) is the signal Sa. The signal Sa is the input signal having a value 0. Then, the determination circuit DCa-1 stores test result information including a determination result in the memory element ME.

The control circuit CC also inputs the test signal and the sequence information to the determination circuit DCd during the input time period from cycle 100 through cycle 900. Then, while the test signal is being inputted, the determination circuit DCd determines whether the input signal being inputted from the selection circuit SCd is the signal Sc. The signal Sc is the input signal whose value changes from 0 to 1. Then, the determination circuit DCd stores test result information including a determination result in the memory element ME.

After S312, the operation at the current test cycle ends.

After all the tests in the test sequence 192 have been completed, the test result information stored in the memory element ME of the test circuit 210 is outputted from an output terminal (illustration omitted) of the test circuit 210. For example, the test result information is read by a computer and is displayed on a display.

By referring to the determination result in each piece of the test result information, a user can identify whether or not there is any malfunction of the input signals in the LSI 200. If the determination result indicates that the correct input signal has not been inputted, the user can identify a malfunction of the input signals in the LSI 200 by referring to the sequence information and the determination circuit identifier.

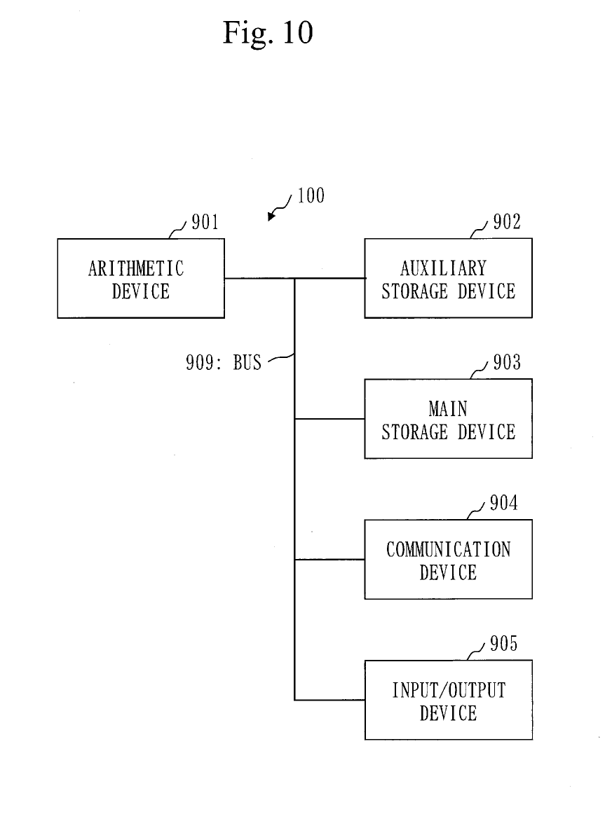

FIG. 10 is a hardware configuration diagram of the test circuit design apparatus 100 according to the first embodiment.

With reference to FIG. 10, the hardware configuration of the test circuit design apparatus 100 according to the first embodiment will be described. Note that the hardware configuration of the test circuit design apparatus 100 may be different from the configuration illustrated in FIG. 10.

The test circuit design apparatus 100 is a computer having an arithmetic device 901, an auxiliary storage device 902, a main storage device 903, a communication device 904, and an input/output device 905.

The arithmetic device 901, the auxiliary storage device 902, the main storage device 903, the communication device 904, and the input/output device 905 are connected to a bus 909.

The arithmetic device 901 is a CPU (Central Processing Unit) that executes programs.

The auxiliary storage device 902 is a ROM (Read Only Memory), a flash memory, or a hard disk device, for example.

The main storage device 903 is a RAM (Random Access Memory), for example.

The communication device 904 communicates in a wired or wireless manner through the Internet, a LAN (Local Area Network), a telephone network, or other types of network.

The input/output device 905 is a mouse, a keyboard, or a display device, for example.

The programs are stored in the auxiliary storage device 902.

For example, an operating system (OS) is stored in the auxiliary storage device 902. Programs that implement each function described as a “part” are also stored in the auxiliary storage device 902.

The programs are stored in the auxiliary storage device 902, and are loaded into the main storage device 903. Then, the programs are read into the arithmetic device 901, and are executed by the arithmetic device 901.

Information, data, files, signal values, and variable values indicating results of processing described as “judge”, “determine”, “extract”, “detect”, “set”, “register”, “select”, “generate”, “input”, and “output” are stored in the main storage device 903 or the auxiliary storage device 902.

According to the first embodiment, the test circuit 210 for testing the input signals inputted to the input terminals of the LSI 200 can be designed. Then, by conducting a test with the test circuit 210, a malfunction of the input signals of the LSI 200 can be easily identified.

The first embodiment is an example of an embodiment of the test circuit design apparatus 100 and the test circuit 210.

That is, the test circuit design apparatus 100 and the test circuit 210 may be constituted without some of the components described in the first embodiment. Further, the test circuit design apparatus 100 and the test circuit 210 may include components not described in the first embodiment.

The processing procedures described using the flowcharts or the like in the first embodiment are examples of processing procedures of a method and a program according to the first embodiment. The method and the program according to the first embodiment may be implemented with processing procedures which are partially different from the processing procedures described in the first embodiment.

In the first embodiment, a “part” may be a “process”, “step”, “program”, “device”, or the like.

Numerous additional modifications and variations are possible in light of the above teachings. It is therefore to be understood that, within the scope of the appended claims, the disclosure of this patent specification may be practiced otherwise than as specifically described herein.

### REFERENCE SIGNS LIST

100: test circuit design apparatus, 110: test circuit design part, 111: overlapping number counting part, 112: determination circuit number decision part, 113: design data generation part, 120: scheduling part, 121: total sequence number counting part, 122: test sequence generation part, 180: data storage part, 181: test information data, 182: determination circuit database, 191: test circuit design data, 192: test sequence, 200: LSI, 210: test circuit, 901: arithmetic device, 902: auxiliary storage device, 903: main storage device, 904: communication device, 905: input/output device, 909: bus

1. A test circuit design apparatus comprising:
a test information data storage part that stores test information data, including a signal identifier and time period information which are being associated with a terminal identifier identifying an input terminal, for each input terminal of a test target circuit having a plurality of input terminals, the signal identifier identifying a type of an input signal to be inputted to the input terminal, the time period information indicating an input time period during which the input signal is inputted;
an overlapping number counting part that counts a first type overlapping number of each unit time period of a test time period during which an input signal to be inputted to the test target circuit is tested, the first type overlapping number indicating a number of terminal identifiers being associated with time period information indicating an input time period which includes the each unit time period and being associated with a first type signal identifier identifying a first type input signal, among terminal identifiers included in the test information data; and
a determination circuit number decision part that decides a first type determination circuit number indicating a number of first type determination circuits which determine whether the first type input signal is inputted, based on the first type overlapping number of each unit time period counted by the overlapping number counting part.

2. The test circuit design apparatus according to claim 1,
wherein the determination circuit number decision part decides that a maximum overlapping number among the first type overlapping number of each unit time period is to be the first type determination circuit number.

3. The test circuit design apparatus according to claim 1, further comprising
a design data generation part that generates design data for a test circuit having a same number of first type determination circuits as the first type determination circuit number decided by the determination circuit number decision part.

4. The test circuit design apparatus according to claim 3, further comprising
a determination circuit database storage part that stores a determination circuit database including determination circuit data which represents a determination circuit and which is being associated with a signal identifier,
wherein the design data generation part generates the design data, using determination circuit data being associated with the first type signal identifier among the determination circuit data included in the determination circuit database, as the determination circuit data representing the first type determination circuit.

5. The test circuit design apparatus according to claim 3,
wherein the test circuit has a first determination circuit out of the same number of first type determination circuits as the first type determination circuit number; a first selection circuit that selects an input signal to be determined by the first determination circuit; and a control circuit that causes the first selection circuit to select an input signal to be inputted to a first input terminal during a first input period during which the first type input signal is inputted to the first input terminal.

6. The test circuit design apparatus according to claim 5,
wherein the control circuit obtains a first terminal identifier and first time period information which are being associated with a first determination circuit identifier identifying the first determination circuit, from a test sequence including a terminal identifier and time period information which are being associated with a determination circuit identifier, and causes the first selection circuit to select an input signal to be inputted to the first input terminal identified with the first terminal identifier during the first input time period indicated by the first time period information.

7. The test circuit design apparatus according to claim 6, further comprising:
a determination circuit database storage part that stores a determination circuit database including a determination circuit identifier which is being associated with a signal identifier; and
a test sequence generation part that obtains the first type signal identifier and the first time period information which are being associated with the first type terminal identifier from the test information data, obtains the first type determination circuit identifier which is being associated with the first type signal identifier from the determination circuit database, and generates the test sequence by associating the first terminal identifier and the first time period information with the first determination circuit identifier which is based on the first type determination circuit identifier.

8. A test circuit design program using test information data,
the test information data being data, including a signal identifier and time period information which are being associated with a terminal identifier identifying an input terminal, for each input terminal of a test target circuit having a plurality of input terminals, the signal identifier identifying a type of an input signal to be inputted to the input terminal, the time period information indicating an input time period during which the input signal is inputted,
the test circuit design program causing a computer to function as
an overlapping number counting part that counts a first type overlapping number of each unit time period of a test time period during which an input signal to be inputted to the test target circuit is tested, the first type overlapping number indicating a number of terminal identifiers being associated with time period information indicating an input time period which includes the each unit time period and being associated with a first type signal identifier identifying a first type input signal, among terminal identifiers included in the test information data; and
a determination circuit number decision part that decides a first type determination circuit number indicating a number of first type determination circuits which determine whether the first type input signal is inputted, based on the first type overlapping number of each unit time period counted by the overlapping number counting part.

9. A test circuit comprising:
a selection circuit for each type of input signal to be inputted to a test target circuit having a plurality of input terminals, the selection circuit selecting an input signal to be inputted to any one of the plurality of input terminals; and
a determination circuit for each selection circuit, the determination circuit determining a type of the input signal which is selected by the selection circuit.

10. The test circuit according to claim 9, further comprising:
a first selection circuit that selects a first input signal to be inputted to a first input terminal among the plurality of input terminals during a first input time period;
a first determination circuit that determines whether the first input signal which is selected by the first selection circuit is a first type input signal;
a second selection circuit that selects a second input signal to be inputted to a second input terminal among the plurality of input terminals during a second input time period which overlaps with the first input time period; and
a second determination circuit that determines whether the second input signal which is selected by the second selection circuit is the first type input signal.

11. The test circuit according to claim 10, further comprising
a control circuit that causes the first selection circuit to select the first input signal to be inputted to the first input terminal during the first input time period during which the first type input signal is inputted to the first input terminal.

12. The test circuit according to claim 11,
wherein the control circuit obtains a first terminal identifier and first time period information which are being associated with a first determination circuit identifier identifying the first determination circuit, from a test sequence including a terminal identifier and time period information which are being associated with a determination circuit identifier, and causes the first selection circuit to select the first input signal to be inputted to the first input terminal identified with the first terminal identifier during the first time period indicated by the first time period information.
